(19) United States
(12) Patent Application Publication
(10) Pub. No.: US 2013/0049034 A1
(43) Pub. Date: Feb. 28, 2013

(54) LIGHT-EMITTING DEVICE

(71) Applicant: Yi Chieh LIN, (US)

(72) Inventor: Yi Chieh LIN, (US)

(21) Appl. No.: 13/611,681

(22) Filed: Sep. 12, 2012

Related U.S. Application Data
(63) Continuation-in-part of application No. 13/223,033, filed on Aug. 31, 2011.

(51) Int. Cl. H01L 33/08

(52) U.S. Cl. 257/88; 257/E33.066

(57) ABSTRACT

This disclosure discloses a light-emitting device. The light-emitting device comprises: a substrate; a first light-emitting stack comprising a first active layer; a bonding interface formed between the substrate and the first light-emitting stack; and a contact structure formed between the first light-emitting stack and the bonding interface and comprising a first contact layer and a second contact layer closer to the bonding interface than the first contact layer; wherein the first contact layer and the second contact layer comprises the same material and the first contact layer has an impurity concentration lower than that of the second contact layer.

### REFERENCE TO RELATED APPLICATION

This application is a continuation-in-part of U.S. patent application Ser. No. 13/223,033, entitled “Light-emitting device”, filed on Aug. 31, 2011, and the content of which is hereby incorporated by reference in its entirety.

### BACKGROUND

1. Technical Field

The present disclosure relates to a light-emitting device, and in particular to a light-emitting device comprising a contact structure.

2. Description of the Related Art

The light-emitting diodes (LEDs) of the solid-state lighting elements have the characteristics of the low power consumption, low heat generation, long operational life, shockproof, small volume, quick response and good opto-electrical property like light emission with a stable wavelength, so the LEDs have been widely used in household appliances, indicator light of instruments, and opto-electrical products, etc. As the opto-electrical technology develops, the solid-state lighting elements have great progress in the light efficiency, operation life and the brightness, and LEDs are expected to become the main stream of the lighting devices in the near future.

Generally speaking, an operation voltage of a light-emitting device is an important parameter in the lighting devices. If the operation voltage is too high, some adverse effects such as high power consumption or low light efficiency are occurred. Therefore, there is a need for reducing the operation voltage of the light-emitting device.

In addition, the LEDs can be further connected to other components in order to form a light emitting apparatus. The LEDs may be mounted onto a submount with the side of the substrate, or a solder bump or a glue material may be formed between the submount and the LEDs, therefore a light-emitting apparatus is formed. Besides, the submount further comprises the circuit layout electrically connected to the electrode of the LEDs.

### SUMMARY OF THE DISCLOSURE

The present disclosure provides a light-emitting device.

The light-emitting device comprises: a substrate; a first light-emitting stack comprising a first active layer; and a contact structure formed between the first light-emitting stack and the substrate and comprising a first contact layer and a second contact layer closer to the substrate than the first contact layer; wherein the first contact layer and the second contact layer comprises the same material and the first contact layer has an impurity concentration lower than that of the second contact layer.

### BRIEF DESCRIPTION OF THE DRAWINGS

The accompanying drawings are included to provide easy understanding of the application, and are incorporated herein and constitute a part of this specification. The drawings illustrate the embodiments of the application and, together with the description, serve to illustrate the principles of the application.

FIG. 1 shows a cross-sectional view of a light-emitting device in accordance with the first embodiment of the present disclosure.

FIGS. 2A to 2D are cross-sectional views showing a method of making the light-emitting device in accordance with the first embodiment of the present disclosure.

FIG. 3 shows a cross-sectional view of a light-emitting device in accordance with the second embodiment of the present disclosure.

FIG. 4 is a cross-sectional view of a light-emitting device in accordance with the third embodiment of the present disclosure.

### DETAILED DESCRIPTION OF THE EMBODIMENTS

To better and concisely explain the disclosure, the same name or the same reference number given or appeared in different paragraphs or figures along the specification should has the same or equivalent meanings while it is once defined anywhere of the disclosure.

The following shows the description of the embodiments of the present disclosure in accordance with the drawings.

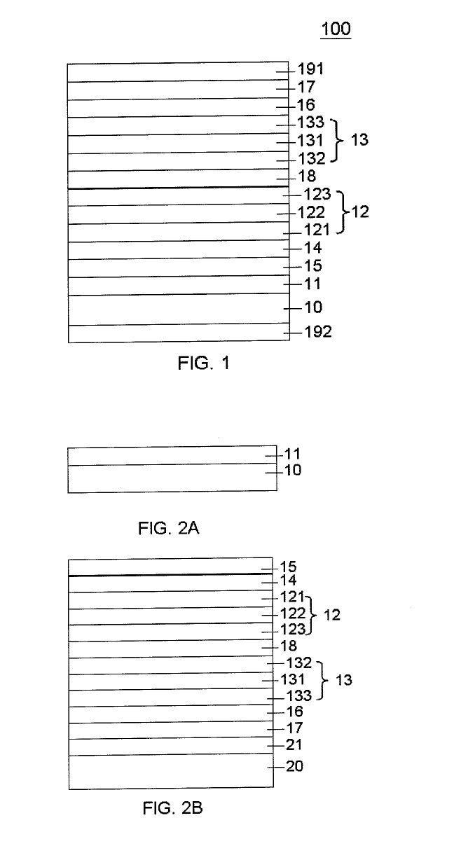

FIG. 1 discloses a light-emitting device 100 according to the first embodiment of the present disclosure. The light-emitting device 100 comprises a substrate 10; a first light-emitting stack 13 disposed on the substrate 10; a contact structure 12 formed on the first light-emitting stack 13 and comprising first, second and third contact layers 121,122, 123. In this embodiment, the first light-emitting stack 13 comprises a first p-type semiconductor layer 132, a first active layer 131, and a first n-type semiconductor layer 133, and the contact structure 12 is formed between the p-type semiconductor layer 132 of the first light-emitting stack 13 and the substrate 10. The light-emitting device 100 further comprises a bonding layer 11 formed between the substrate 10 and the contact structure 12, a transparent conductive layer 14 formed between the contact structure 12 and the substrate 10, and a mirror layer 15 formed between the transparent conductive layer 14 and the substrate 10. The mirror layer 15 can be a reflecting layer for reflecting the light emitted from the light-emitting stack 13. In addition, the light-emitting device 100 further comprises a n-window layer 16 formed on the first light-emitting stack 13, an etching stop layer 17 formed on the n-window layer 16, and a p-window layer 18 formed between the p-type semiconductor layer 132 and the third contact layer 123. An n-electrode 191 and a p-electrode 192 are respectively formed on the etching stop layer 17 and the substrate 10 for electrically connecting to an external electrode (not shown).

In this embodiment, the first contact layer 121 is close to the substrate 10, the third contact layer 123 is close to the first light-emitting stack 13, and the second contact layer 122 is sandwiched between the first and third contact layers 121, 123. The contact structure 12 has a graded bandgap along a direction from the first light-emitting stack 13 to the substrate 10, that is, the first contact layer 121 has a bandgap greater than that of the third contact layer 123, and the second contact layer 122 has a bandgap between that of the first and third contact layers 121, 123.

Moreover, each of the first, second and third contact layers 121, 122, 123 comprises a doping material as an impurity. The doping material comprises Mg, Be, Zn, C, and combination thereof. Therefore, the first, second, and third contact layers comprise the same conductivity, which is a p-type conductivity in the embodiment. In one embodiment, the doping material in the first contact layer 121 is different from that in the second and/or third contact layers 122, 123. A doping concentration (or impurity concentration) of the first contact layer 121 is higher than the doping concentration (or impurity concentration) of the second and/or third contact layers 122, 123. The doping concentration of the first contact layer 121 is higher than 10¹⁹ cm⁻³ for ohmically contacting the transparent conductive layer 14, and the doping concentration of each of the second and third contact layers 122, 123 is higher than 10¹⁸ cm⁻³. It is noted that the conductivity of the first, second, and third contact layers 121, 122, 123 can be different. For example, the second contact layer 122 has an n-type conductivity, and the first and third contact layers 121, 123 have a p-type conductivity; or the first and second contact layers 121, 122 have a p-type conductivity, and the third contact layer 123 has an n-type conductivity such that there is a tunnel effect between the first, second, and third contact layers 121, 122, 123. The doping concentration of the first, second, and third contact layers is higher than 10¹⁹ cm⁻³ for obtaining the tunnel effect.

In this embodiment, the first light-emitting stack 13 and the contact structure 12 comprise different materials. For example, the first contact layer 121 comprises GaAsP or (AlₓGa₁₋ₓ)_{y}In_{1-y}P; 0≦x≦0.1; 0.9≦y≦1. The second contact layer 122 comprises (AlₓGa₁₋ₓ)_{y}In_{1-y}P; 0.05≦x≦0.3; 0.45≦y≦0.55. The third contact layer 123 comprises (AlₓGa₁₋ₓ)_{y}In_{1-y}P; 0≦x≦0.1; 0.45≦y≦0.55. Each of the first n-type semiconductor layer 133, the first active layer 131, and the first p-type semiconductor layer 132 comprises AlGaAs, InGaAs, or GaAs. The contact structure 12 has a thickness ranging from 50 nm to 280 nm. The first contact layer 121 has a thickness ranging from 35 nm to 120 nm, the second contact layer 122 has a thickness ranging from 10 nm to 80 nm, and the third contact layer 121 has a thickness ranging from 5 nm to 80 nm. The bonding layer 11 comprises metal which comprises gold (Au), indium (In), tin (Sn), and combinations thereof. The etching stop layer 17 comprises InGaP or GaAs.

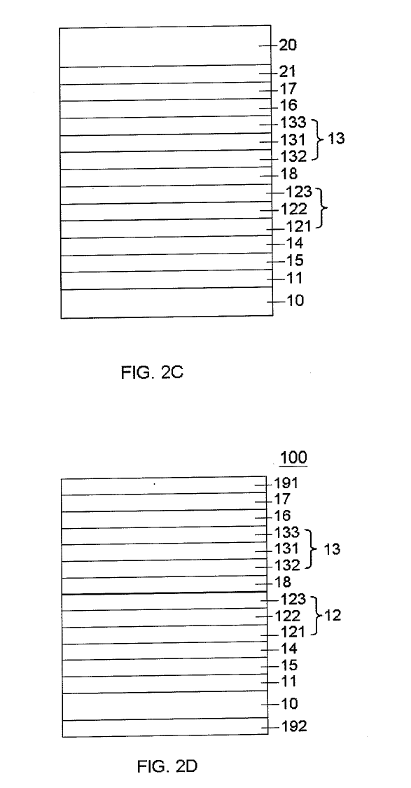

FIGS. 2A and 2B are cross-sectional views showing a method of making the light-emitting device of the first embodiment. Referring to FIG. 2A, the bonding layer 11 is formed on the Si substrate 10. Referring to FIG. 2B, a growth substrate 20 is provided, and a buffer layer 21, the etching stop layer 17, the n-window layer 16, the first light-emitting stack 13, the p-window layer 18, and the contact structure 12 are subsequently formed on the growth substrate 20 by epitaxial growth. The transparent conductive layer 14 is formed on the contact structure 12 and the mirror layer 15 is formed on the transparent conductive layer 14. Referring to FIG. 2C, the substrate 20 is bonded to the mirror layer 15 through the bonding layer 11, thereby forming a bonding interface therebetween. Subsequently, the buffer layer 21 is removed to separate the growth substrate 20 and the etching stop layer 17. The n-electrode 191 and the p-electrode 192 are respectively formed on the etching stop layer 17 and the substrate 10 to form the light-emitting device 100, as shown in FIG. 2D.

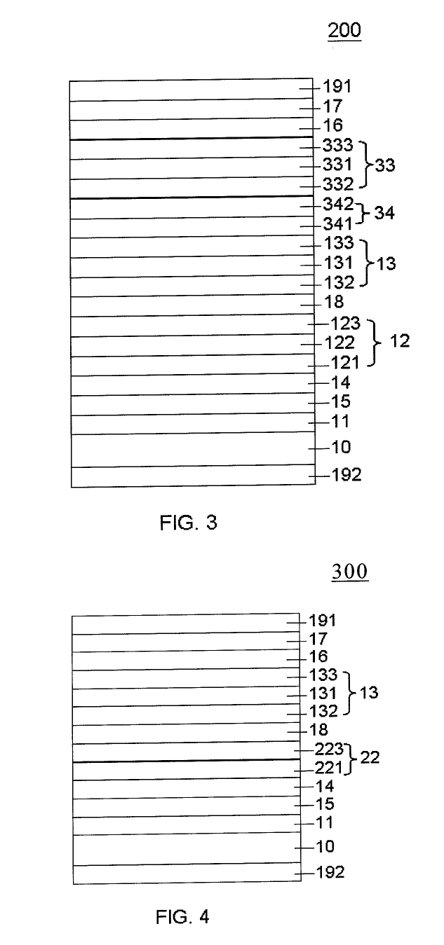

FIG. 3 shows a light-emitting device 200 according to the second embodiment of the present disclosure. The second embodiment of the light-emitting device 200 further comprises a second light-emitting stack 33 vertically formed or stacked on the first light-emitting stack 13. The second light-emitting stack 33 comprises a second p-type semiconductor layer 332, a second active layer 331, and a second n-type semiconductor layer 333. Each of the second n-type semiconductor layer 333, the second active layer 331, and the second p-type semiconductor layer 332 comprises AlGaAs, InGaAs, or GaAs. Each of the first and second active layer 131, 331 emits light having a dominant wavelength ranging from 840 nm to 1000 nm (between 840 nm to 1000 nm). In another embodiment, the first active layer 131 and the second active layers 331 emit light having the same dominant wavelengths. In one embodiment, the first active layer 131 emits light having a dominant wavelength with a difference of 1-10 nm from the dominant wavelength of the second active layer 331. Furthermore, the light-emitting device 200 comprises a tunnel junction 34 formed between the first and second light-emitting stacks 13, 33. The tunnel junction 34 comprises an n-type layer 341 and a p-type layer 342. Each of the n-type layer 341 and the p-type layer 342 comprises GaAs, AlGaAs, InGaP, or AlGaInP. The n-type layer 341 has a thickness of 20 nm-160 nm, and the p-type layer 342 has a thickness of 20 nm-120 nm.

FIG. 4 shows a light-emitting device 300 according to the third embodiment of the present disclosure. The third embodiment of the light-emitting device 300 has the similar structure with the light-emitting device 100 of the first embodiment, except that the contact structure 22 comprises two layers of the first and third contact layers 221, 223. In this embodiment, the first and third contact layers 221, 223 comprise the same or different material. For example, each of the first and third contact layers 221, 223 comprises GaP or (AlₓGa₁₋ₓ)_{y}In_{1-y}P; 0≦x≦0.8; 0.48≦y≦0.52. In addition, the first and third contact layers 221, 223 comprise a doping material or an impurity, and the impurity concentration of the first contact layer 221 is 1.5 to 5 times of the impurity concentration of the third contact layer 223. The first contact layer 221 has an impurity concentration not lower than 3×10¹⁹ cm⁻³ for directly ohmic contacting with the transparent conductive layer 14 and the third contact layer 223 has an impurity concentration not greater than 3×10¹⁹ cm⁻³ and further not lower than 10¹⁸ cm⁻³ for reducing the light from absorbing by the third contact layer 223. In one embodiment, when the first and third contact layers 221, 223 comprises the same material, there is no interface between the first and third contact layers 221, 223 and the contact structure 22 is formed by a two-step method. The two-step method comprises separately forming the first and third contact layers 221, 223 having different impurity concentration by metal-organic chemical vapor deposition (MOCVD). Alternatively, the contact structure 22 can be formed by growing a single layer and adjusting the impurity concentration during the process of forming the single layer such that the single layer has the different doping concentration. In one embodiment, the contact layer 22 has a graded impurity concentration increasing along a direction from the transparent conductive layer 14 to the first light-emitting stack 13. The higher the impurity concentration, the lower the contact resistivity. Furthermore, a thickness of the first contact layer 221 is greater than that of the third contact layer 223. The thickness of the first contact layer 221 is not less than 35 nm and further not greater than 120 nm. The thickness of the third contact layer 223 is not less than 5 nm, and further not greater than 80 nm.

### EXAMPLES

### Example 1 (E1)

The light-emitting device has a structure as shown in FIG. 1. The buffer layer 21 of n-GaAs, the etching stop layer 17 of n-InGaP, the n-window layer 16 of AlGaAs, the n-type semiconductor layer 133 of AlGaAs, the active layer 131 of AlGaAs/InGaAs, the p-type semiconductor layer 132 of AlGaAs, the third contact layer 123 of Zn-doped InGaP, the second contact layer 122 of Zn-doped AlGaInP and the first contact layer 121 of C-doped GaP are sequentially grown on the growth substrate 20 of GaAs. The transparent conductive layer 14 made of ITO is formed on the first contact layer 121 by evaporating or sputtering. The mirror layer 15 comprising a multi-layer structure of Ag/Ti/Pt/Au is formed on the transparent conductive layer 14. The substrate 10 made of Si is bonded to the mirror layer 15 by the bonding layer 11 of Au/In using metal bonding process, and then the GaAs buffer layer 11 is etched so as to remove the growth substrate 20 from the etching stop layer 17. Subsequently, the p-type electrode 192 is formed on the substrate 10 and the n-type electrode 191 is formed on the etching stop layer 17. In the embodiment, the size of the light-emitting device is 14 mil×14 mil.

It is noted that the substrate 10 can be bonded to the mirror layer 15 by a direct bonding without the bonding layer 11. The direct bonding is performed under a temperature of 200-500° C. and a pressure ranging from 1 mtorr to 760 torr, and a composite material is formed at the interface between the substrate 10 and the mirror layer 15 during the direct bonding process for forming the bonding interface therebetween.

### Example 2 (E2)

The light-emitting device of Example 2 has a similar structure with that of Example 1, except that the contact structure 22 comprises two layers of the first and third contact layer 221, 223, as shown in FIG. 4. The first contact layer 221 is C-doped GaP and the third contact layer 223 of Zn-doped InGaP.

TABLE 1

| | V (volt) | Po (watt) |
|---|---|---|
| E1 | 1.59 | 859.1 |
| E2 | 1.63 | 858.8 |

Table 1 shows experimental results of Examples 1 and 2. The light-emitting device of Example 1 has the operation voltage (V) of 1.59 volt at a current 100 mA and the power (Po) of 859.1 watt. The light-emitting device of Example 2 has the operation voltage (V) of 1.63 volt at a current 100 mA and the power (Po) of 858.8 watt. The light-emitting device of Example 1 has a lower operation voltage than that of Example 2, which indicates the second contact layer 222 having a bandgap energy between that of the first and third contact layers 221, 223 can reduce the operation voltage.

### Example 3 (E3)

The light-emitting device of Example 3 has a similar structure with that of Example 2, except that the first and third contact layer 221, 223 have the same material of GaP with different impurity concentration. The impurity concentration of the first contact layer 221 is 4×10¹⁹ cm⁻³ and the impurity concentration of the third contact layer 223 is 2×10¹⁹ cm⁻³. The size of the light-emitting device is 42 mil×42 mil.

### Comparative Example 1 (CE1)

The light-emitting device of Comparative Example 1 has a similar structure with that of Example 3, except that the contact structure 22 merely comprises a contact layer of GaP with the impurity concentration of 2×10¹⁹ cm⁻³.

TABLE 2

| | V (volt) | Po (watt) |
|---|---|---|
| E3 | 2.83 | 858.95 |
| CE1 | 2.9 | 859.37 |

Table 2 shows experimental results of Example 3. The light-emitting device of Example 3 has the operation voltage (V) of 2.83 volt at a current 100 mA and the power (Po) of 858.95 watt. The light-emitting device of Comparative Example 1 has the operation voltage (V) of 2.9 volt at a current 100 mA and the power (Po) of 859.37 watt. The light-emitting device of Example 3 has a lower operation voltage than that of Comparative Example 1, which indicates the contact structure having two contact layers of GaP with varied impurity concentration can reduce the operation voltage.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting device comprising:
a substrate;
a first light-emitting stack comprising a first active layer; and
a contact structure formed between the first light-emitting stack and the substrate and comprising a first contact layer and a second contact layer closer to the substrate than the first contact layer;
wherein the first contact layer and the second contact layer comprises the same material and the first contact layer has an impurity concentration lower than that of the second contact layer.

2. The light-emitting device of claim 1, further comprising a bonding interface formed between the substrate and the first light-emitting stack.

3. The light-emitting device of claim 1, wherein the first light-emitting stack and the contact structure comprise different materials.

4. The light-emitting device of claim 1, wherein the contact structure comprises GaP or (AlₓGa₁₋ₓ)_{y}In_{1-y}P; 0≦x≦0.8; 0.48≦y≦0.52.

5. The light-emitting device of claim 1, wherein the first contact layer and the second contact layer have the same conductivity type.

6. The light-emitting device of claim 1, wherein the first contact layer and the second contact layer are p-type semiconductor.

7. The light-emitting device of claim 1, wherein the first contact layer and the second contact layer have an impurity comprising Mg, Be, Zn, C, and combination thereof.

8. The light-emitting device of claim 1, further comprising a second light-emitting stack comprising a second active layer stacked on the first light-emitting stack.

9. The light-emitting device of claim 8, further comprising a tunnel junction formed between the first light-emitting stack and the second light-emitting stack.

10. The light-emitting device of claim 8, wherein the first active layer or the second active layer comprises AlGaAs, InGaAs, or GaAs.

11. The light-emitting device of claim 8, wherein the first active layer and the second active layer comprise AlGaAs, and emit light having dominant wavelengths between 840 nm and 1000 nm.

12. The light-emitting device of claim 8, wherein the first active layer and the second active layer emit light having the same dominant wavelengths.

13. The light-emitting device of claim 8, wherein the first active layer emit light has a dominant wavelength with a difference of 1-10 nm from the dominant wavelength of the second active layer.

14. The light-emitting device of claim 1, wherein the second contact layer has an impurity concentration 1.5 to 5 times of the impurity concentration of the first contact layer.

15. The light-emitting device of claim 1, wherein the second contact layer has an impurity concentration not lower than 3×10¹⁹ cm⁻³.

16. The light-emitting device of claim 1, wherein the first contact layer has an impurity concentration not greater than 3×10¹⁹ cm⁻³.

17. The light-emitting device of claim 1, wherein a thickness of the second contact layer is greater than that of the first contact layer.

18. The light-emitting device of claim 17, wherein the thickness of the second contact layer is not less than 35 nm.

19. The light-emitting device of claim 17, wherein the thickness of the first contact layer is not less than 5 nm.
